(19) United States
(12) Patent Application Publication
(10) Pub. No.: US 2013/0277754 A1
(43) Pub. Date: Oct. 24, 2013

(54) Semiconductor Integrated Structure

(71) Applicants: Chia-Wen Liang, Hsinchu City (TW); Yi-Chung Sheng, Tainan City (TW); Shih-Chieh Hsu, New Taipei City (TW); Yao-Chang Wang, Tainan City (TW); Chi-Horn Pai, Tainan City (TW); Jie-Ning Yang, Ping-Tung County (TW); Chi-Sheng Tseng, Tainan City (TW)

(72) Inventors: Chia-Wen Liang, Hsinchu City (TW); Yi-Chung Sheng, Tainan City (TW); Shih-Chieh Hsu, New Taipei City (TW); Yao-Chang Wang, Tainan City (TW); Chi-Horn Pai, Tainan City (TW); Jie-Ning Yang, Ping-Tung County (TW); Chi-Sheng Tseng, Tainan City (TW)

(21) Appl. No.: 13/451,540

(22) Filed: Apr. 20, 2012

(51) Int. Cl. H01L 27/06

(52) U.S. Cl. 257/379; 257/E27.016

(57) ABSTRACT

The present invention provides a resistor structure including a substrate, an ILD layer, a transistor and a resistor. The substrate includes a resistor region and an active region. The ILD layer is disposed directly on the substrate. The transistor is disposed in the active region in the ILD layer wherein the transistor includes a metal gate. The resistor is disposed in the resistor region above the ILD layer, wherein the resistor directly contacts the ILD layer.

### BACKGROUND OF THE INVENTION

1. Field of the Invention

The invention relates to an integrated structure, and more particularly, to an integrated structure having a resistor structure and a metal gate transistor.

2. Description of the Prior Art

To increase the performance of transistors, metal gates are prevalently used in the semiconductor field: the metal gates competent to the high dielectric constant (high-k) gate dielectric layer are used to replace the traditional poly-silicon gates to be the control electrode. The metal gate approach can be categorized to the gate first process and the gate last process. And the gate last process gradually replaces the gate first process because a range of material choices for the high-k gate dielectric layer and the metal gate are expanded.

Additionally, resistors are elements which are often used for providing regulated voltage and for filtering noise in a circuit. The resistors generally include poly-silicon and silicide layers.

In the current semiconductor field, though the fabricating processes are improved with the aim of reaching high yields, it is found that integration of the manufacturing methods of those different kinds of semiconductor devices is very complicated and difficult. Therefore, a method for fabricating a resistor integrated with a transistor having metal gate is still in need.

### SUMMARY OF THE INVENTION

According to one embodiment of the present invention, the present invention provides an integrated structure including a substrate, an ILD layer, a transistor and a resistor. The substrate includes a resistor region and an active region. The ILD layer is disposed directly on the substrate. The transistor is disposed in the active region in the ILD layer wherein the transistor includes a metal gate. The resistor is disposed in the transistor region above the ILD layer, wherein the resistor directly contacts the ILD layer.

According to another embodiment of the present invention, the present invention provides an integrated structure having a substrate, an ILD layer, a transistor, a resistor, a dummy resistor and a contact plug. The substrate includes a resistor region and an active region. The ILD layer is disposed directly on the substrate. The resistor is disposed in the transistor region above the ILD layer, wherein the resistor directly contacts the ILD layer. The dummy resistor is disposed in the resistor region in the ILD layer, wherein the dummy resistor includes at least a metal layer. The contact plug penetrates the resistor and directly contacts the metal layer of the dummy resistor.

According to another embodiment of the present invention, the present invention provides an integrated structure including a substrate, an ILD layer, a transistor and a resistor. The substrate includes a resistor region and an active region. The ILD layer is disposed directly on the substrate. The transistor is disposed in the active region in the ILD layer wherein the transistor includes a metal gate. The resistor is disposed in the resistor region in the ILD layer, wherein the resistor includes a U-shaped metal layer.

The integrated structure provided in the present invention can be integrated with a transistor having metal gate. Consequently, the manufacturing steps can be streamlined and the cost can be reduced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 6 are schematic diagrams of the method of forming the integrated structure according to the first embodiment of the present invention.

FIG. 7 is a schematic diagram of integrated structure according to the second embodiment of the present invention.

FIG. 8 to FIG. 14 are schematic diagrams of the method of forming the integrated structure according to the third embodiment of the present invention.

FIG. 15 to FIG. 19 are schematic diagrams of the method of forming the integrated structure according to the fourth embodiment of the present invention.

### DETAILED DESCRIPTION

To provide a better understanding of the presented invention, preferred embodiments will be detailed. The preferred embodiments of the present invention are illustrated in the accompanying drawings with numbered elements.

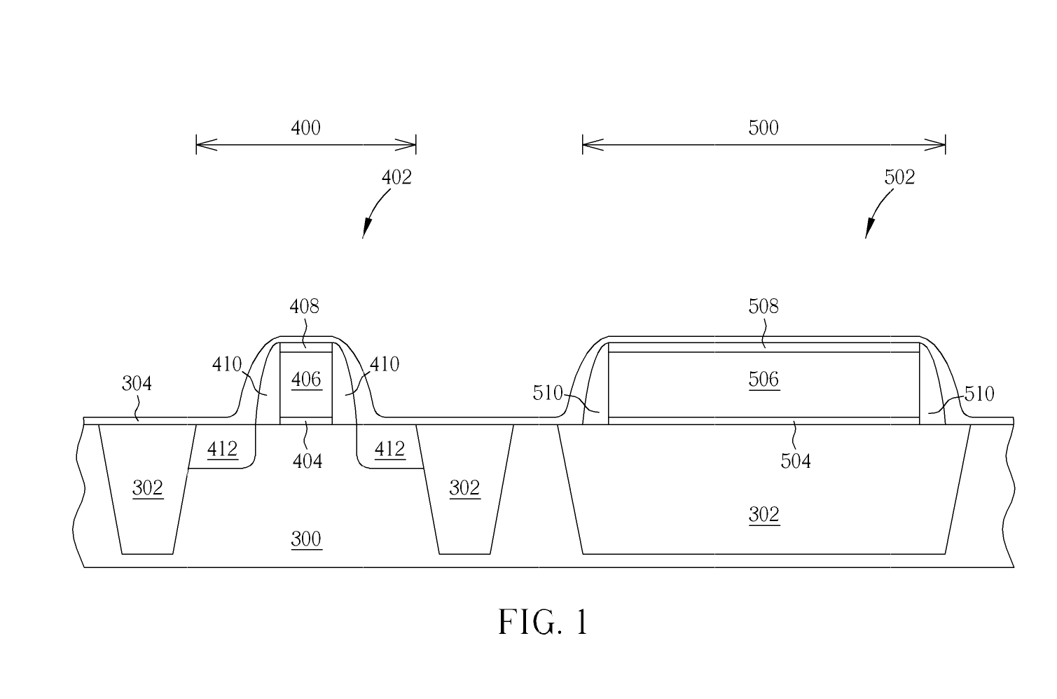

Please refer to FIG. 1 to FIG. 6, which are schematic diagrams of the method of forming the resistor structure according to the first embodiment of the present invention. As shown in FIG. 1, a substrate 300 is provided. The substrate 300 can be a silicon substrate, an epitaxial silicon substrate, a silicon germanium substrate, a silicon carbide substrate or a silicon-on-insulator (SOI) substrate, but is not limited thereto. An active region 400 is defined on the substrate 300 to form a transistor in the following steps, and a resistor region 500 is defined on the substrate 300 to form a resistor in the following steps. A plurality of shallow trench isolations (STI) 302 are formed in the substrate 300. A part of the shallow trench isolations 302 surround the active area 400, while a part of the shallow trench isolations 302 is disposed in the substrate 300 in the resistor region 500. Then, a plurality of semiconductor manufacturing processes are carried out to form a transistor 402 in the active region 400 and a dummy resistor 502 in the resistor region 500. In one embodiment, the transistor 402 has an interfacial layer 404, a sacrifice layer 406, a cap layer 408, a spacer 410 and a source/drain region 412. The dummy resistor 502 has an interfacial layer 504, a sacrificial layer 506, a cap layer 508 and a spacer 510. In one preferred embodiment, the interfacial layer 404 and interfacial layer 504 include SiO₂, the sacrificial layer 406 and sacrificial layer 506 include poly-silicon, the cap layer 408 and cap layer 508 include SiN, the spacer 410 and spacer 510 include SiN, and the source/drain region 412 is formed by implanting appropriate dopant in the substrate 300. It is noteworthy that the material of the components in the transistor 402 and the dummy resistor 502 are not limited to the aforementioned embodiment. Also, the transistor 402 or the dummy resistor 502 may include other structures, such as silicide layer, or one or more than one passivation layers, which are known in the art and are not described in detail. After the formation of the transistor 402 and the dummy resistor 502, a contact etch stop layer (CESL) 304 is formed on the substrate 300 to cover the transistor 402 and the dummy resistor 502.

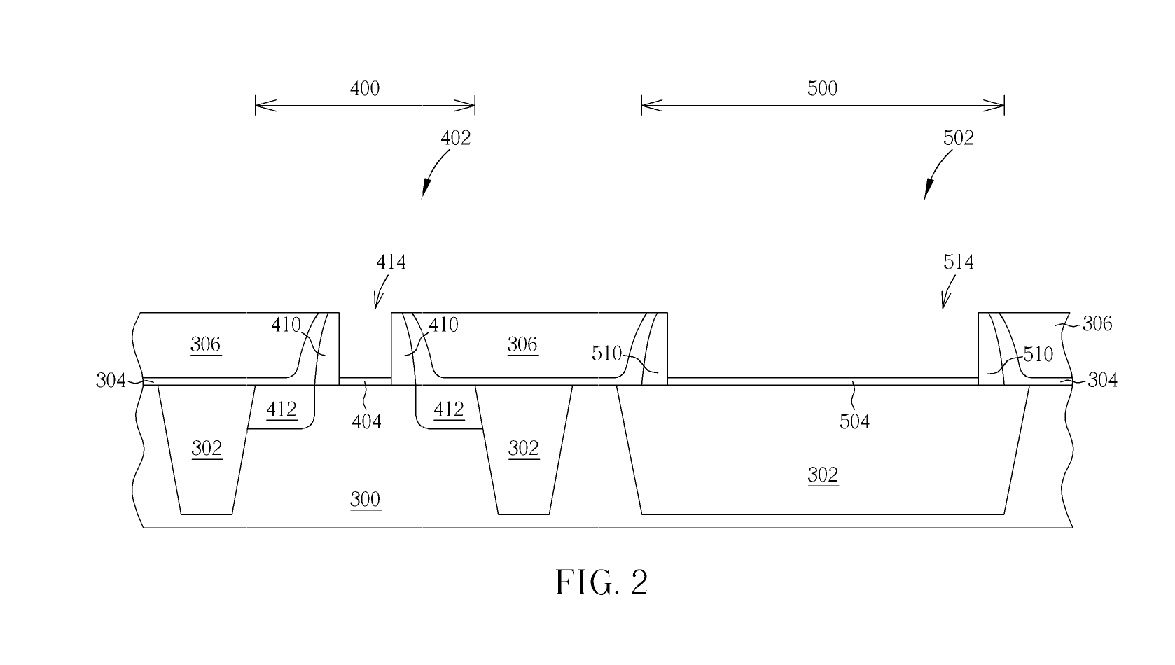

As shown in FIG. 2, an inter-layer dielectric (ILD) 306 is formed on the contact etch stop layer 304. In one embodiment, the ILD layer 306 may be made of silicon dioxide (SiO₂), TEOS, PETEOS or other low dielectric materials. Then, a planarization process, such as a chemical mechanical polish (CMP) process or an etching back process or their combination, is performed to remove a part of the ILD layer 306, a part of the CESL 304, a part of the spacer 410, a part of the spacer 510, and completely remove the cap layer 408 and the cap layer 508, until exposing the sacrifice layer 406 of the transistor 402 and the sacrifice layer 506 of the dummy resistor 502. Then, an etching process such as a wet etching and/or a dry etching is carried out to remove the sacrifice layer 406 of the transistor 402 and the sacrifice layer 506 of the dummy resistor 502, thereby forming a first trench 414 in the active region 400 and a second trench 514 in the resistor region 500. In another embodiment, the interfacial layer 404 and the interfacial layer 504 can be further removed.

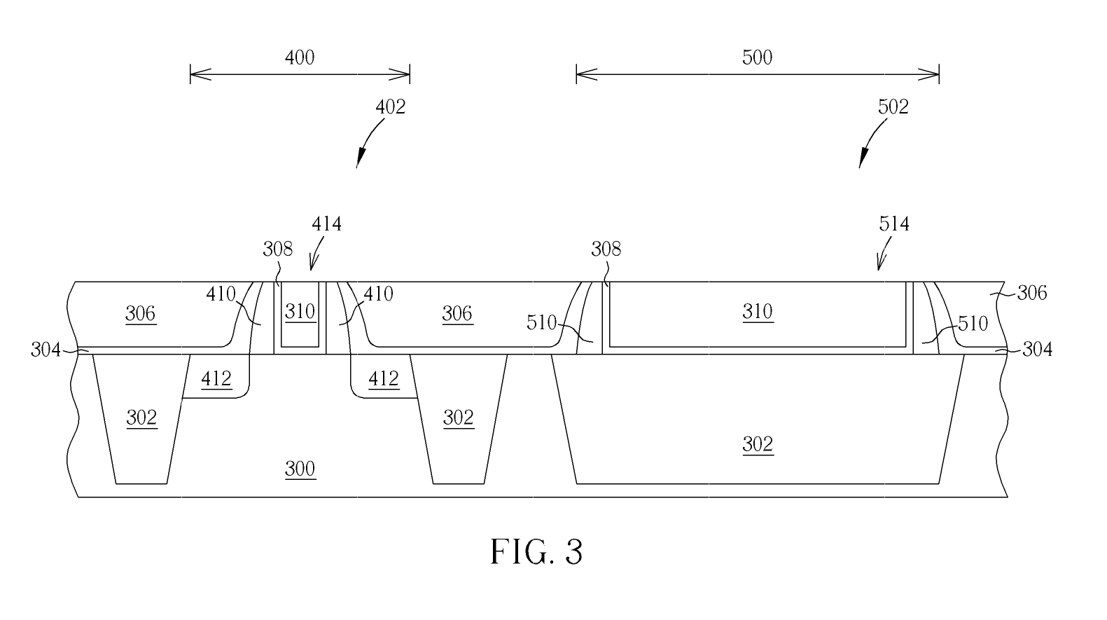

As shown in FIG. 3, a high-k dielectric layer 308 and a metal layer 310 are formed on the substrate 300. The high-k dielectric layer 308 and the metal layer 310 are completely filled in the first trench 414 and the second trench 514. In one preferred embodiment of the present invention, the high-k dielectric layer 308 may include materials selected from the group consisting of hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate, (SrBi₂Ta₂O₉, SBT), lead zirconate titanate (PbZrₓTi₁₋ₓO₃, PZT), and barium strontium titanate (BaₓSr₁₋ₓTiO₃, BST), but is not limited thereto. The metal layer 310 can be aluminum (Al), titanium (Ti), tantalum (Ta), tungsten (W), niobium (Nb), molybdenum (Mo), copper (Cu), titanium nitride (TiN), titanium carbide (TiC), tantalum nitride (TaN), titanium tungsten (Ti/W) or titanium or titanium nitride (Ti/TiN), or their combination. In another embodiment, one or more than more barrier layers (not shown) or work function metal layer (not shown) can be formed between the high-k dielectric layer 308 and metal layer 310 in accordance with the electrical requirements of the transistor 402. Subsequently, a planarization process is performed to remove the high-k dielectric layer 308 and the metal layer 310 outside the first trench 414 and the second trench 514, thereby making the top surface of the metal layer 310 leveled with ILD layer 306. In this way, a U-shaped high-dielectric layer 308 is formed on the surface of the first trench 414 and the second trench 514.

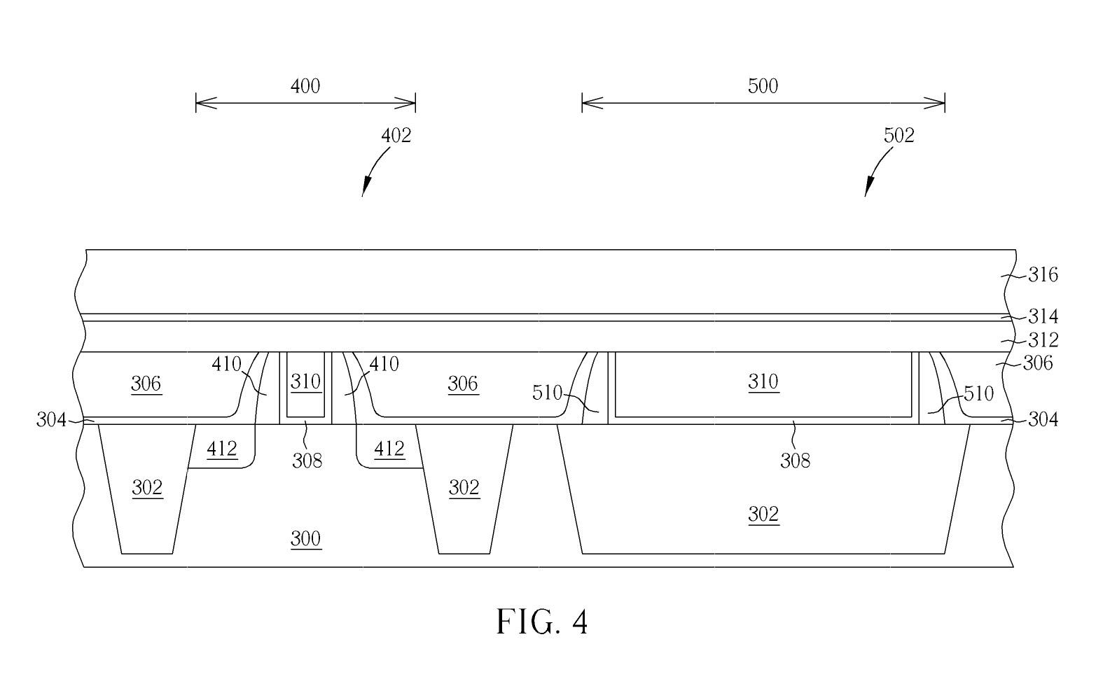

As shown in FIG. 4, a first dielectric layer 312, a conductive layer 314 and a second dielectric layer 316 are formed on the substrate 300 to cover and directly contact the ILD layer 306. In one preferred embodiment, the first dielectric layer 312 includes undoped silicon carbide or silicon carbide doped with nitrogen or silicon carbide doped with oxygen having a thickness approximately between 200 angstroms to 300 angstroms. The conductive layer 314 includes any conductive material such as titanium nitride with a thickness approximately between 20 angstroms to 6o angstroms. The second dielectric layer 316 includes silicon nitride, with a thickness approximately between 300 angstroms to 600 angstroms.

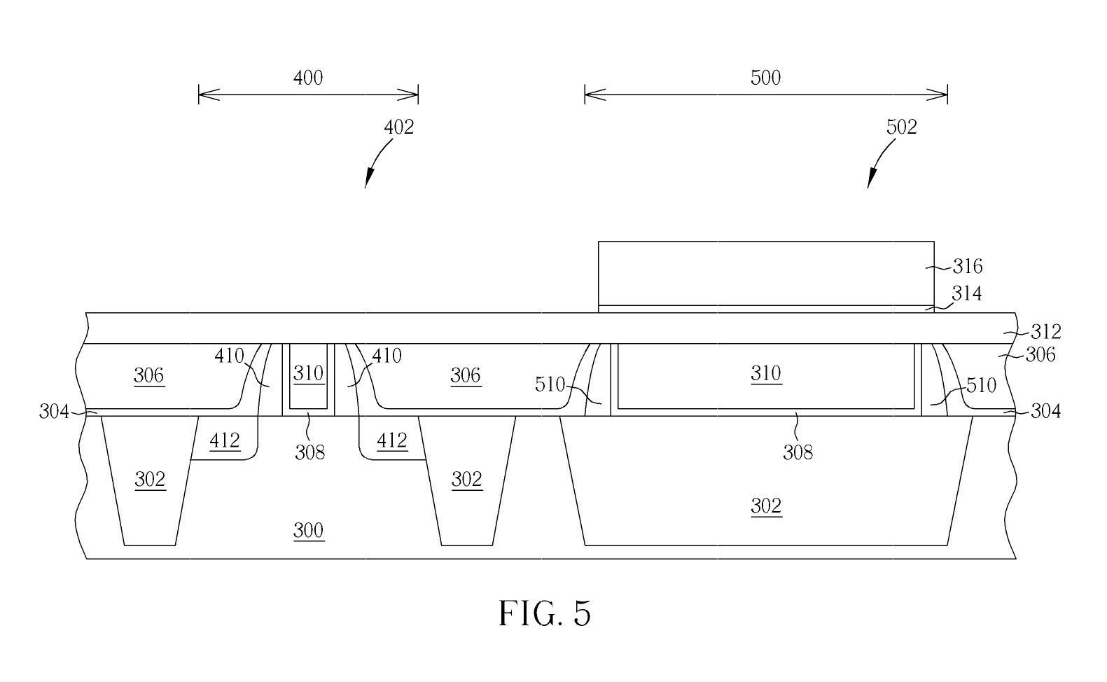

As shown in FIG. 5, an etching process is carried out to remove the second dielectric layer 316 and conductive layer 314 other than the resistor region 500. For example, a patterned photoresist layer (not shown) can be formed, and an etching process is performed by using this patterned photoresist layer as a mask, thereby making the second dielectric layer 316 and conductive layer 314 vertical align with each other.

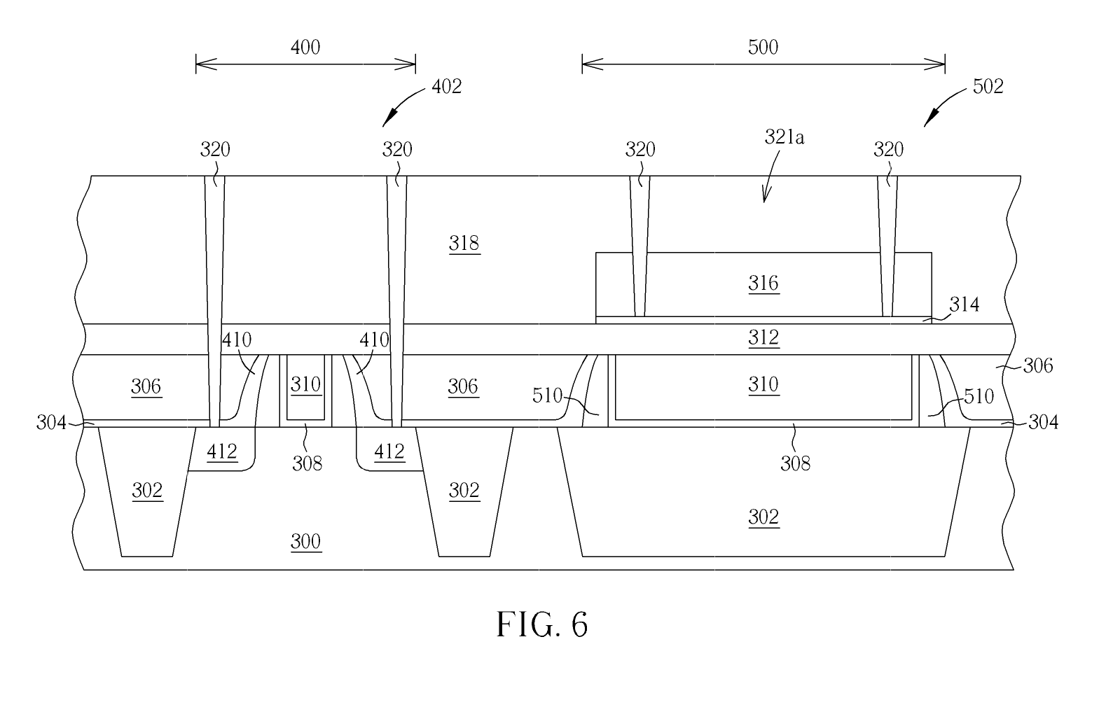

As shown in FIG. 6, an interlayer dielectric layer 318 is formed on the substrate 300, and a planarization process can further be performed optionally. Finally, a plurality of contact plugs 320 are formed in the interlayer dielectric layer 318, the second dielectric layer 316, in which at least two contact plugs 320 direct contact the conductive layer 314, and at least two contact plugs 320 respectively contact the source/drain region 412. Consequently, a resistor structure 321a is therefore formed above the ILD layer 306. As shown in FIG. 6, the resistor structure 321a is disposed directly above the dummy resistor 502 and is disposed above ILD layer 306. The resistor structure 321a is composed of “the first dielectric layer 312—the conductive layers 314—the second dielectric layer 316”, which is like a sandwich structure. As shown, the second dielectric layer 316 and the conductive layer 314 are vertical aligned with each other.

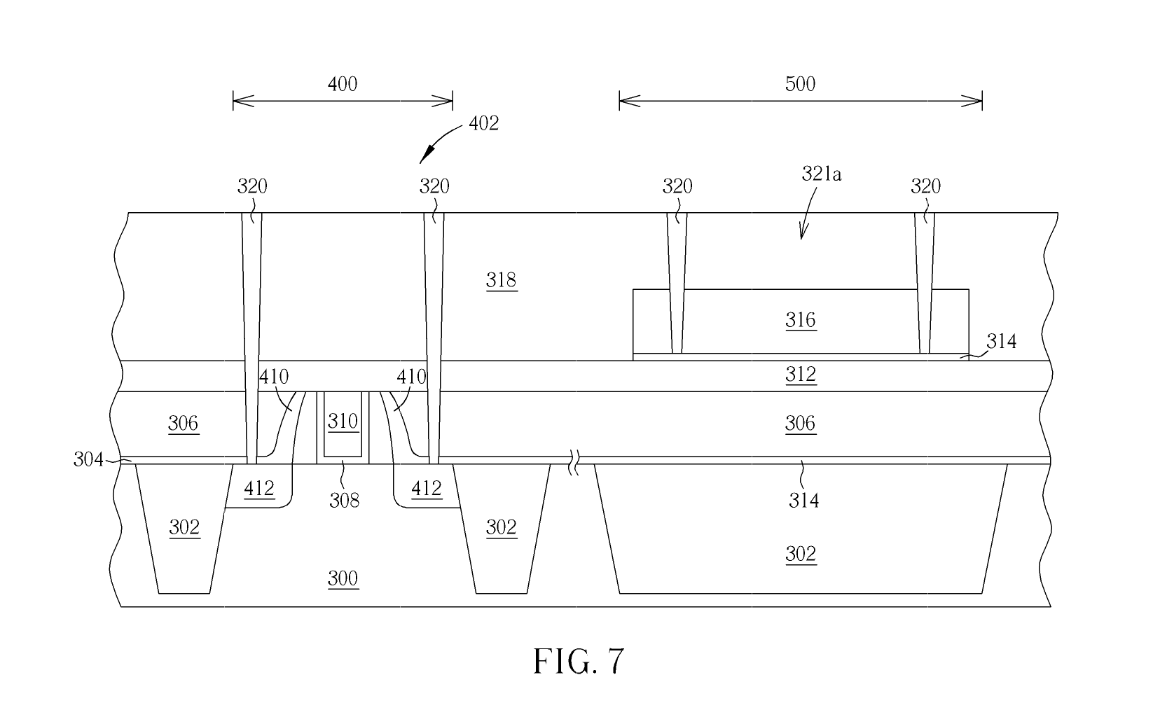

In another embodiment, the resistor structure 321a can be disposed in other places according to different designs of the products. Please refer to FIG. 7, which is a schematic diagram showing the integrated structure according to the second embodiment of the present invention. As shown in FIG. 7, the semiconductor integrated structure includes transistor 402 and resistor structure 321a. The resistor 402 is disposed in the ILD layer 306 in the active region 400. The resistor structure 321a is disposed directly over the ILD layer 306 in the resistor region 500, but is not disposed over the dummy resistor 502. That is, the ILD layer 306 is disposed between the resistor structure 321a and the STI 302. Preferably, only the ILD layer 306 is disposed between the resistor structure 321a and the STI 302

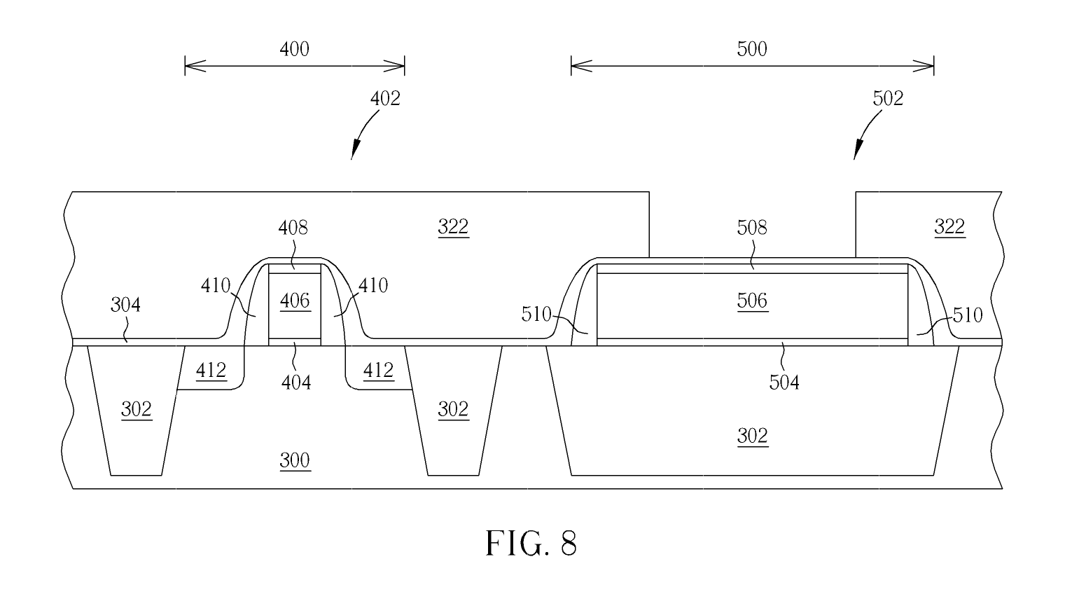

Please refer to FIG. 8 to FIG. 14, which are schematic diagrams showing the steps of forming the resistor structure according to the third embodiment of the present invention. After forming the structure as in FIG. 1, please see FIG. 7. A patterned photoresist layer 322 is formed on the substrate 300. The patterned photoresist layer 322 has an opening located in the resistor region 500, wherein the width of the opening is less than that of the sacrificial layer 5o6.

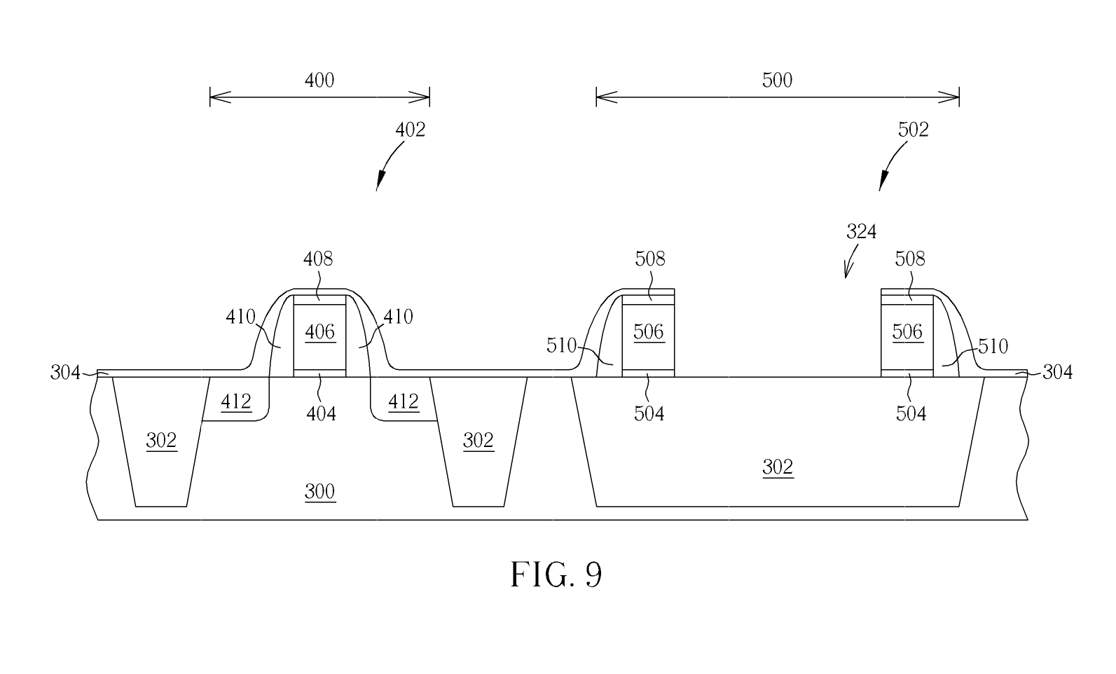

As shown in FIG. 9, an etching process is performed by using the patterned photoresist layer 322 as a mask to remove the exposed contact etch stop layer 304, the cap 508, the sacrificial layer 5o6 and the interfacial layer 504, until exposing the shallow trench isolation 302 in the substrate 300, thereby forming a third trench 324 in the dummy resistor 502. It is worth noting that there is still sacrificial layer 5o6 on both sidewalls of the third trench 324.

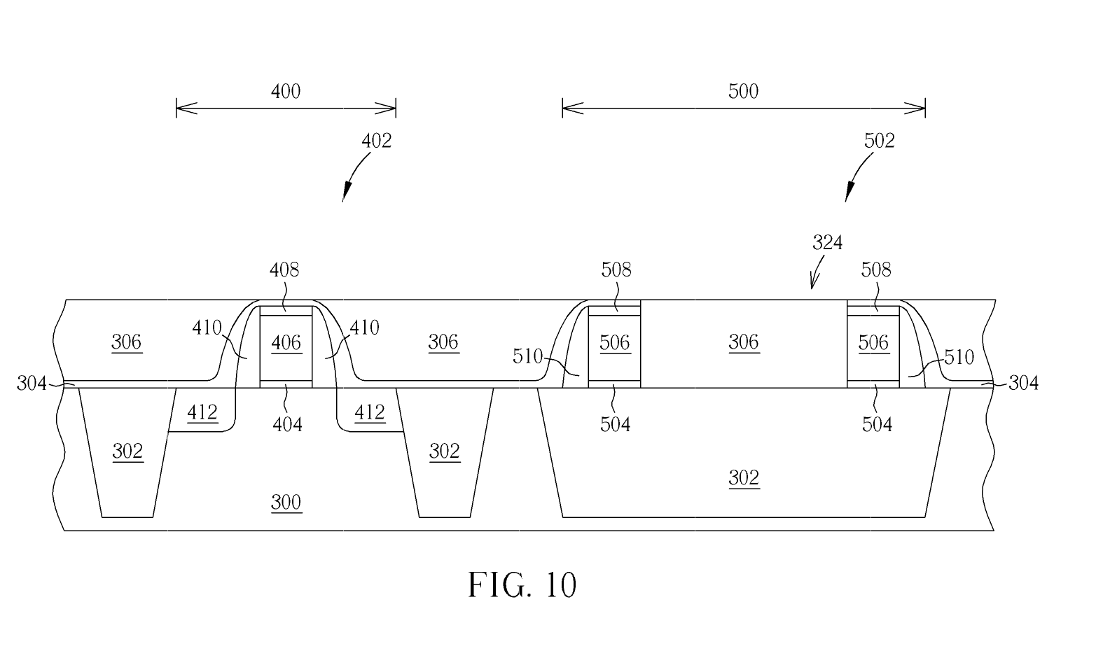

As shown in FIG. 10, an ILD layer 306 is formed fully on the substrate 300. The ILD layer 306 would cover the contact hole etch stop layer 304, and completely fills the third trench 324. In one embodiment, the ILD layer 306 may be made of silicon dioxide (SiO₂), TEOS, PETEOS or other low dielectric materials. Then, a planarization process, such as a chemical mechanical polish (CMP) process or an etching back process or their combination, is performed to remove a part of the ILD layer 306, a part of the CESL 304, a part of the spacer 410, a part of the spacer 510, and completely remove the cap layer 408 and the cap layer 508, until exposing the sacrifice layer 406 of the transistor 402 and the sacrifice layer 5o6 of the dummy resistor 502.

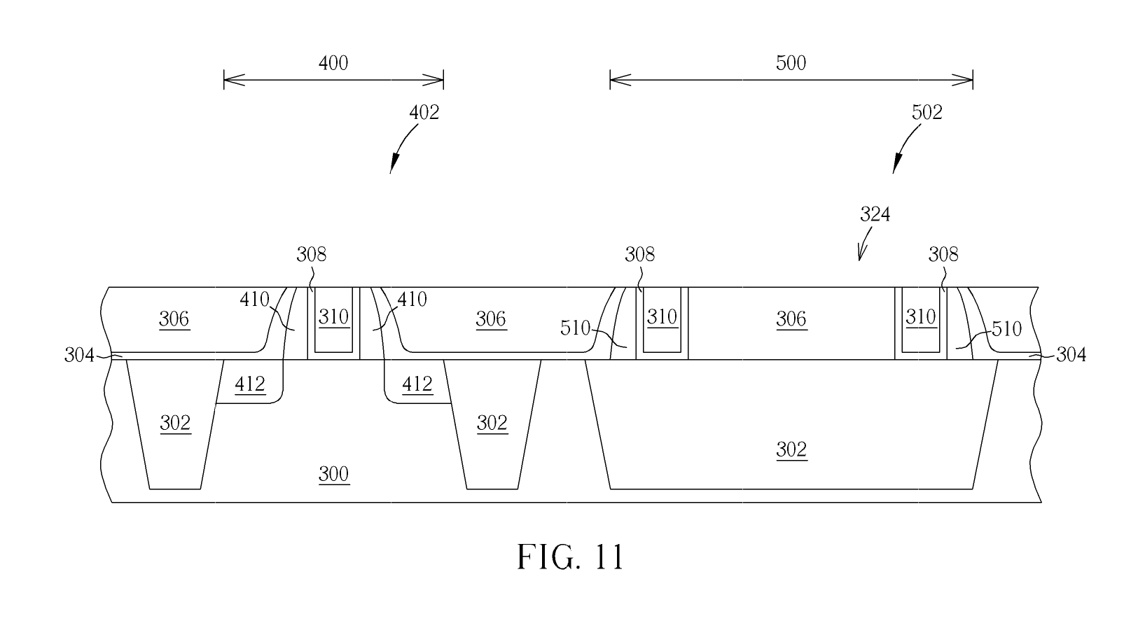

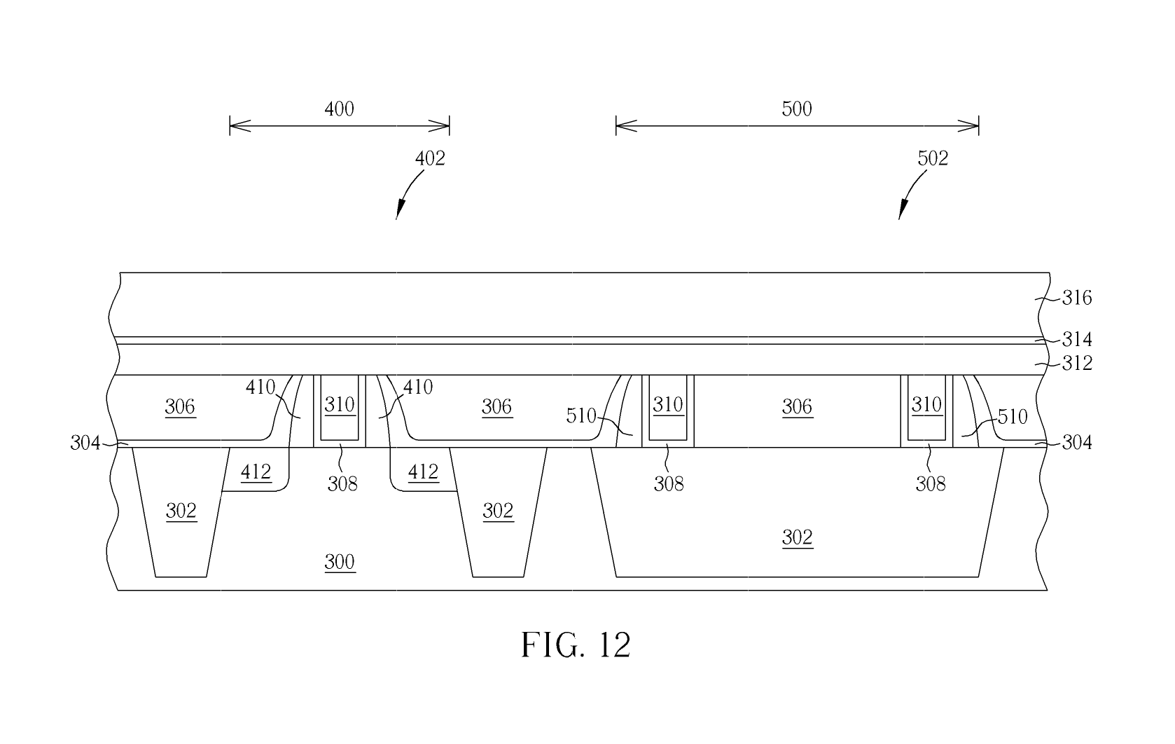

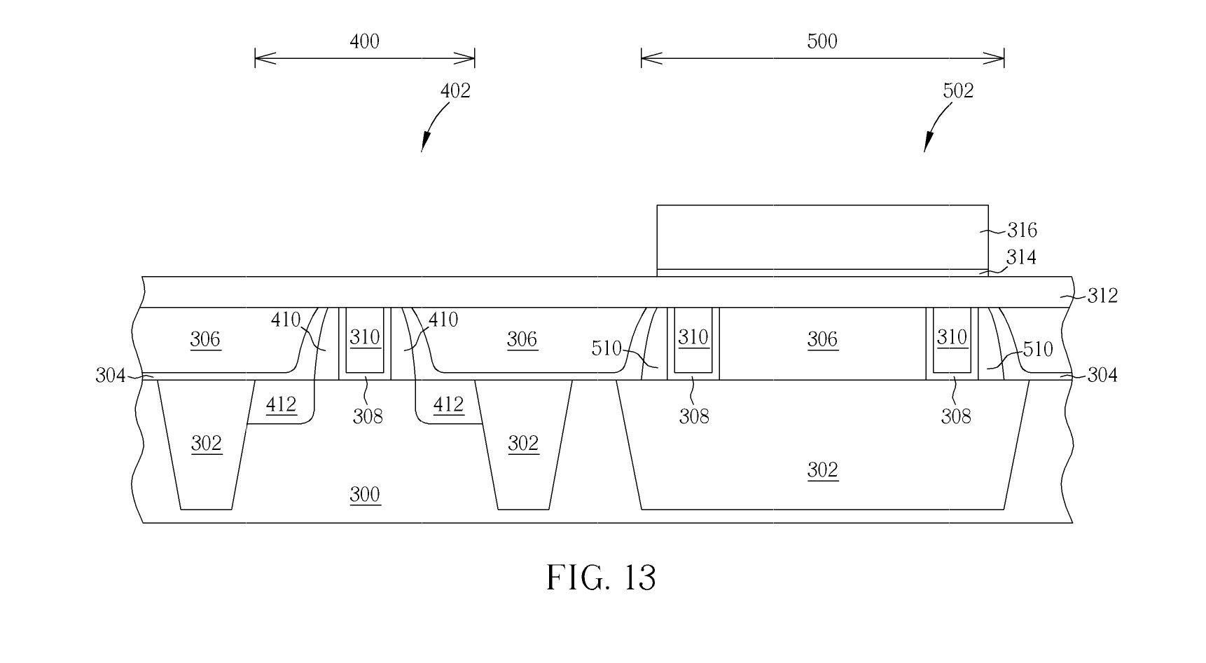

As shown in FIG. 11, an etching process such as a wet etching and/or a dry etching is carried out to completely remove the sacrifice layer 406 of the transistor 402 and the sacrifice layer 5o6 of the dummy resistor 502. Then, a high-k dielectric layer 308 and a metal layer 310 are formed on the substrate 300. A planarization process is carried out to make the high-k dielectric layer 308 and the metal layer 310 leveled with the ILD layer 306. As shown in FIG. 12, a first dielectric layer 312 is formed on the substrate 300 to directly cover the ILD layer 306. Then, a first conductive layer 314 and a second dielectric layer 316 are formed on the first dielectric layer 316. Finally, as shown in FIG. 13, an etching process is performed by using a patterned mask (not shown) as a mask to remove the second dielectric layer 316 and conductive layer 314 other than the resistor region 500, thereby making the second dielectric layer 316 and conductive layer 314 vertical align with each other.

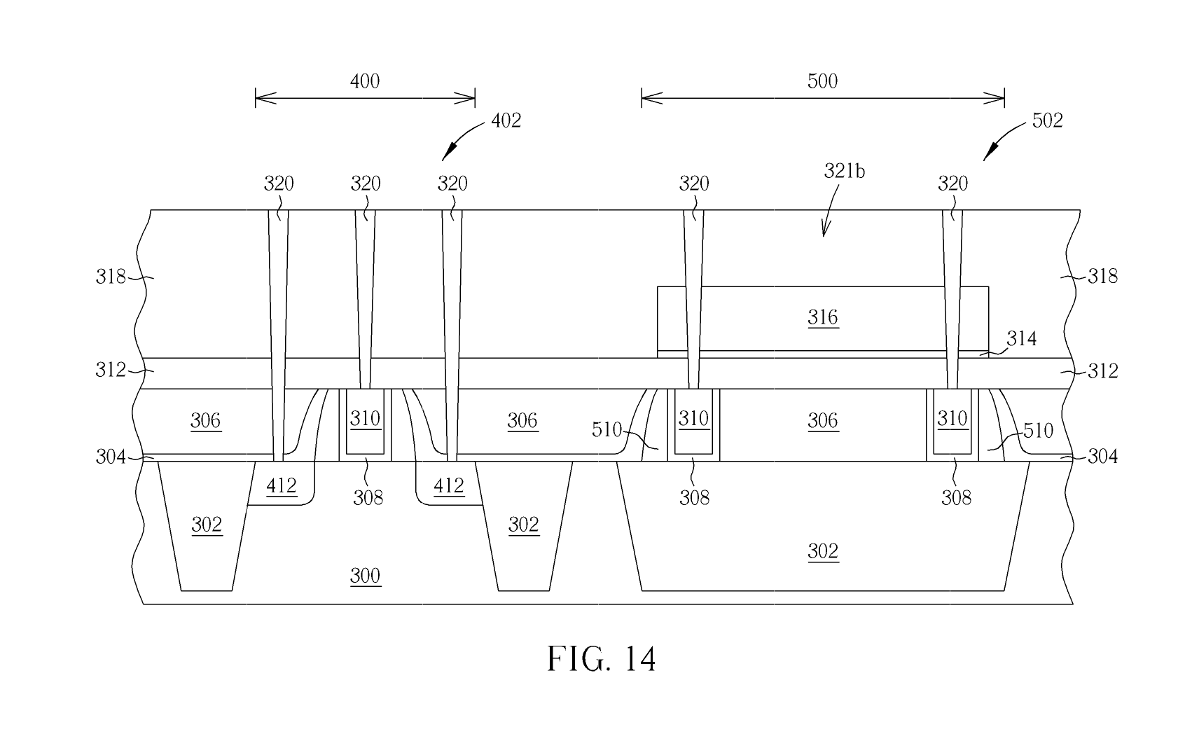

As shown in FIG. 14, an interlayer dielectric layer 318 is formed on the substrate 300, and a planarization process can further be performed optionally. Finally, a plurality of contact plugs 320 are formed in the interlayer dielectric layer 318, the second dielectric layer 316, the conductive layer 314, the first dielectric layer 312, in which at least two contact plugs 320 direct contact the metal layer 310 in the resistor region 500, and at least two contact plugs 320 respectively contact the source/drain region 412. Consequently, a resistor structure 321b is therefore formed above the ILD layer 306. As shown in FIG. 13, the resistor structure 321b is disposed directly above the dummy resistor 502 and is disposed above ILD layer 306. The resistor structure 321b is composed of “the first dielectric layer 312—the conductive layers 314—the second dielectric layer 316”, which is like a sandwich structure. As shown, the second dielectric layer 312 and the conductive layer 314 are vertical aligned with each other. It is one salient feature in the present embodiment that the contact plug 320 contact the metal layer 310 in the dummy resistor 502. Because the conductive layer 314 is thin so it might be difficult for the contact plug 320 to land thereon. Accordingly, the contact plug 320 in the present invention is to land on the metal layer 314 so the landing accuracy can be improved and the resistance value can be increased as well.

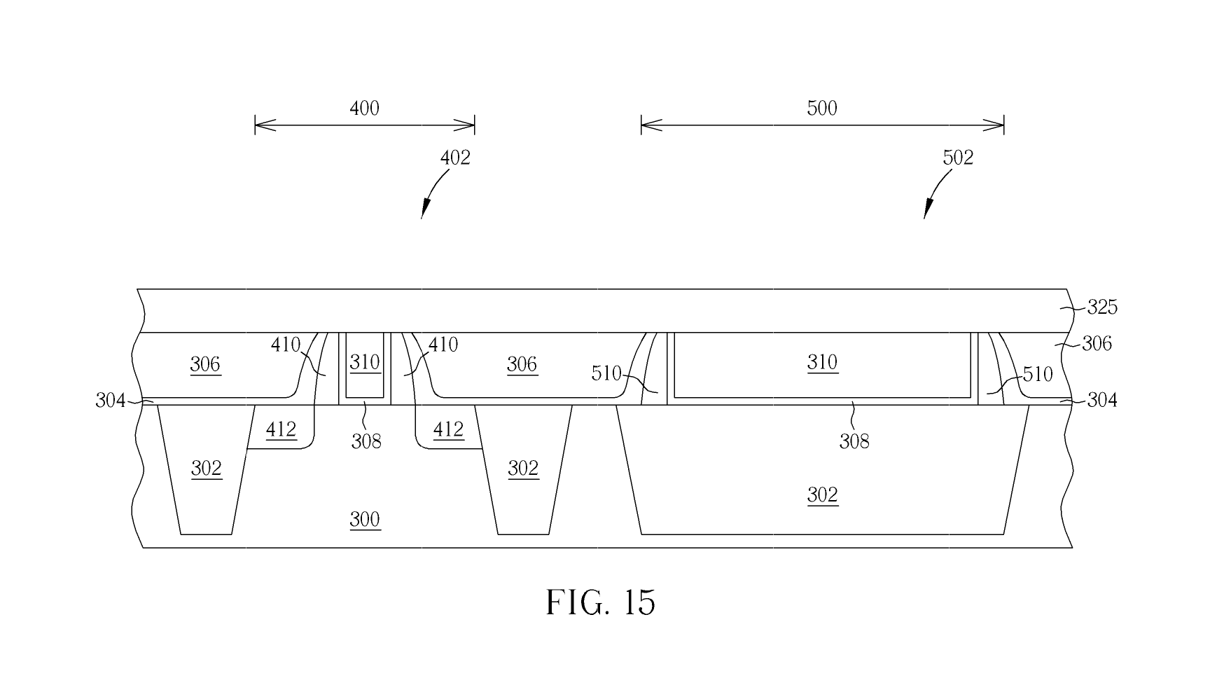

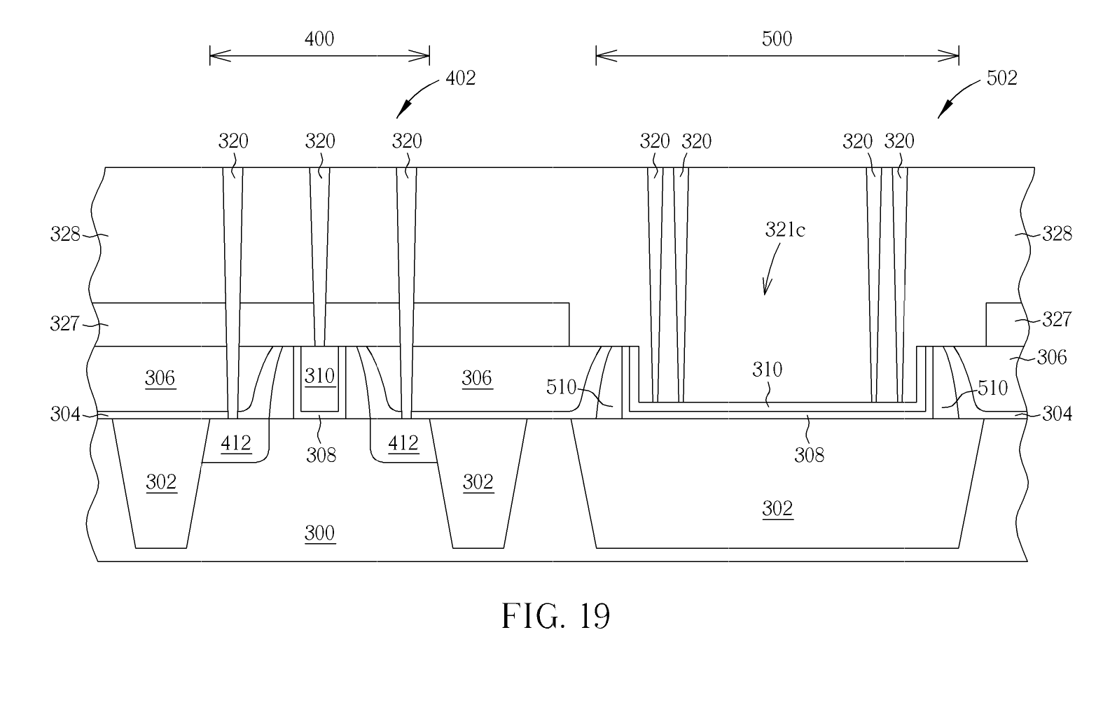

Please refer to FIG. 15 to FIG. 19, which are schematic diagrams showing the steps of forming the resistor structure according to the fourth embodiment of the present invention. After the steps in FIG. 1 to FIG. 3, please see FIG. 15, an inner dielectric layer 325 is formed on the substrate 300, such as a SiO₂ layer or a TEOS layer which is made of the same material as the first dielectric layer 312 described above and has a thickness approximately between 200 angstroms to 400 angstroms.

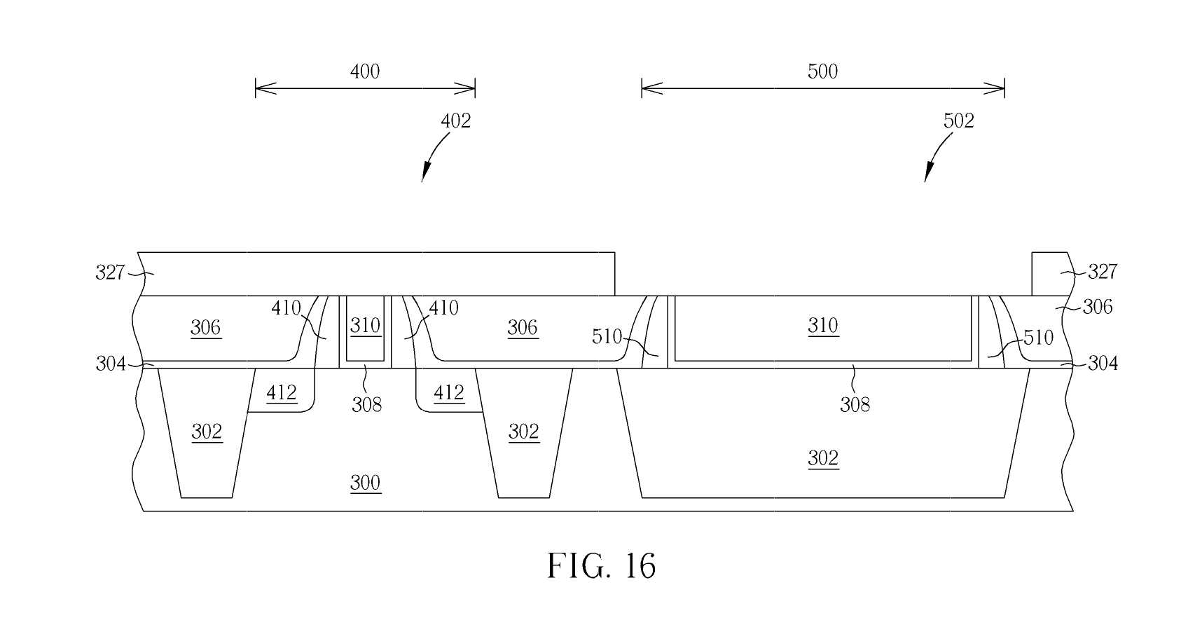

Then, as shown in FIG. 16, a lithography process and an etching process are performed to remove a part of the interlayer dielectric layer 325, thereby forming the patterned interlayer dielectric layer 327. The patterned interlayer dielectric layer 327 would expose the underlay metal layer 310.

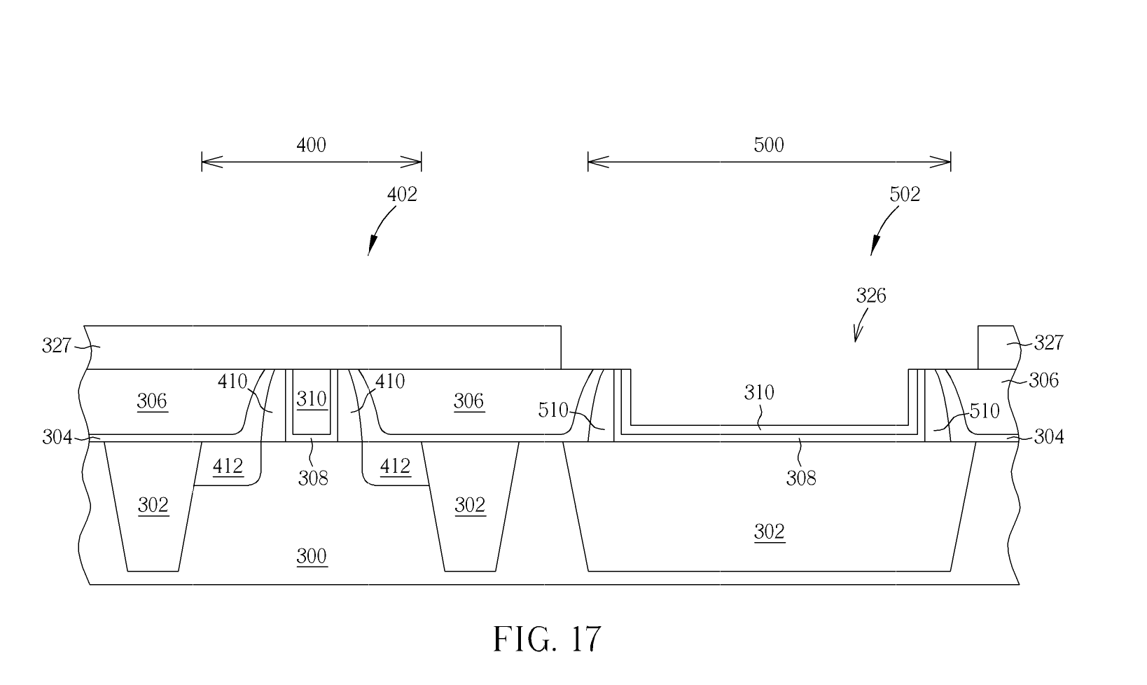

As shown in FIG. 17, a wet etching and/or a dry etching process is carried out to remove a part of the metal layer 310 in the resistor region 500, thereby forming a fourth trench 326 in the resistor region 500. In one preferred embodiment of the present invention, the metal layer 310 is etched to a uniform thickness, for example, to about 20-60 angstroms to form a U-shaped structure. It is worth noting that the high-k dielectric layer 310 (or the barrier layer or the work function metal layer) below of the metal layer 310 are not removed preferably. In another embodiment, the metal layer 310 can be completely removed while the barrier layer or the work function metal layer is remained on the substrate 300.

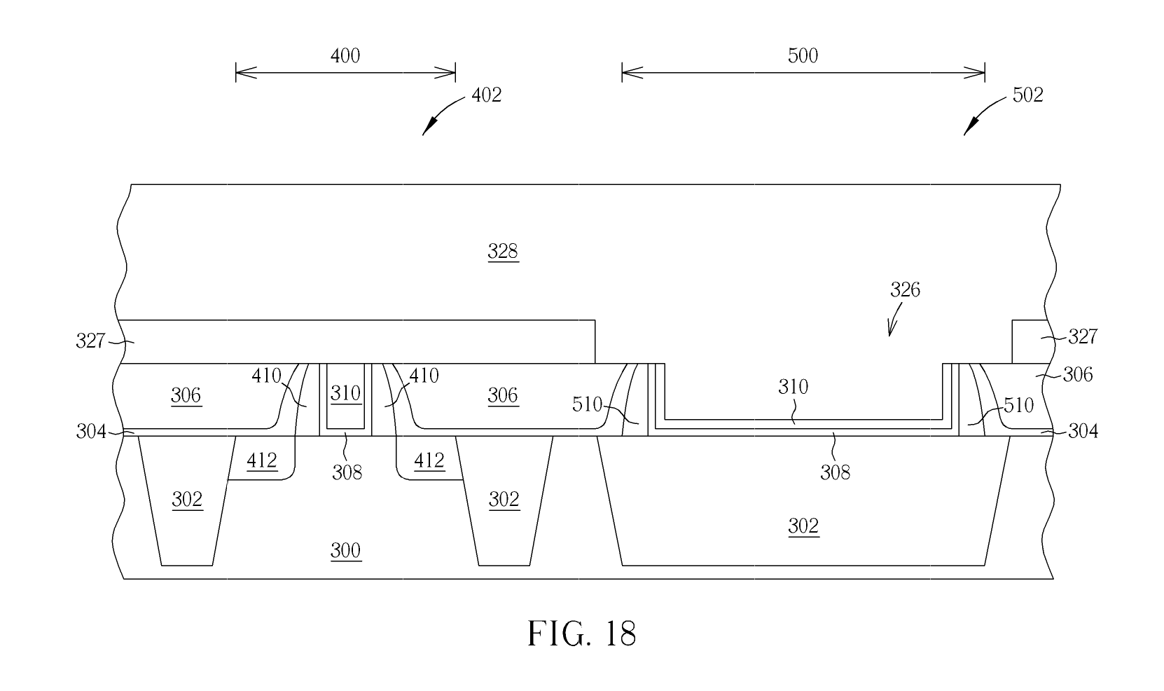

As shown in FIG. 18, a second interlayer dielectric layer 328 is formed on the substrate 300 to completely fill the fourth trench 326 in the resistor region 500. Lastly, in FIG. 18, a plurality of contact plugs 320 are formed, wherein at least two contact plugs 320 penetrate through the second interlayer dielectric layer 328 to land on the metal layer 310 (or the barrier layer or the work function metal layer) in the resistor region 500. Consequently, a resistor structure 321c is therefore formed in the resistor region 500. As shown in FIG. 17, the resistor structure 321c is composed of “the high-k dielectric layer 308—the metal layer 310—the second interlayer dielectric layer 328”, which is like a sandwich structure. In addition, the resistor structure 321c has a U-shaped metal layer 310 disposed in the dummy resistor 502.

The integrated structure provided in the present invention includes a transistor having metal gate and a transistor. Consequently, the manufacturing steps can be streamlined and the cost can be reduced.

Those skilled in the art will readily observe that numerous modifications and alterations of the device and method may be made while retaining the teachings of the invention. Accordingly, the above disclosure should be construed as limited only by the metes and bounds of the appended claims.

1. An integrated structure, comprising:
a substrate, wherein a resistor region and an active region are defined on the substrate;
an ILD layer disposed directly on the substrate;
a transistor disposed in the ILD layer in the active region, wherein the transistor comprises a metal gate; and
a resistor disposed on the ILD layer in the resistor region, wherein the resistor directly contacts the ILD layer.

2. The integrated structure according to claim 1, wherein the resistor comprises a first dielectric layer, a conductive layer and a second dielectric layer.

3. The integrated structure according to claim 2, wherein the second dielectric layer and the conductive layer are vertically aligned with each other.

4. The integrated structure according to claim 2, further comprising a contact plug penetrating through the second dielectric layer and contacting the conductive layer.

5. The integrated structure according to claim 2, wherein the first dielectric layer directly contacts the ILD layer.

6. The integrated structure according to claim 1, further comprising a dummy transistor disposed in the ILD layer in the resistor region and below the resistor, wherein the dummy resistor comprises a metal layer and a high-k dielectric layer, and the high-k dielectric layer has a U-shaped structure.

7. The integrated structure according to claim 1, wherein only the ILD layer is disposed between the resistor and the substrate.

8. The integrated structure according to claim 1, further comprising a shallow trench isolation disposed in the substrate in the resistor region.

9. An integrated structure, comprising:
a substrate, wherein a resistor region and an active region are defined on the substrate;
an ILD layer disposed directly on the substrate;
a transistor disposed in the ILD layer in the active region, wherein the transistor comprises a metal gate;
a resistor disposed on the ILD layer in the resistor region, wherein the resistor directly contacts the ILD layer;
a dummy resistor disposed in the ILD layer in the resistor region, wherein the dummy resistor comprises at least a metal layer; and
a contact plug penetrating through the resistor and directly contacting the metal layer in the dummy resistor.

10. The integrated structure according to claim 9, wherein the resistor comprises a first dielectric layer, a conductive layer and a second dielectric layer.

11. The integrated structure according to claim 10, wherein the second dielectric layer and the conductive layer are vertically aligned with each other.

12. The integrated structure according to claim 9, wherein the dummy resistor comprises two metal layers, wherein a part of the ILD layer is disposed between the two metal layers.

13. The integrated structure according to claim 12, wherein the dummy resistor further comprise two high-k dielectric layer respectively disposed between the two metal layers and the substrate, and the high-k dielectric layer has a U-shaped structure.

14. The integrated structure according to claim 9, further comprising a shallow trench isolation disposed in the substrate in the resistor region.

15. An integrated structure, comprising:
a substrate, wherein a resistor region and an active region are defined on the substrate;
an ILD layer disposed directly on the substrate;
a transistor disposed in the ILD layer in the active region, wherein the transistor comprises a metal gate; and
a resistor disposed in the ILD layer in the resistor region, wherein the resistor has a U-shaped structure.

16. The integrated structure according to claim 15, further comprising a trench disposed in the resistor region, wherein the resistor is disposed in the trench.

17. The integrated structure according to claim 15, wherein the resistor further comprises a high-k dielectric layer disposed in the trench, and the high-k dielectric layer has a U-shaped structure.

18. The integrated structure according to claim 15, wherein the resistor comprises a U-shaped metal layer.

19. The integrated structure according to claim 18, further comprising a contact plug penetrating through the ILD layer and contact the U-shaped metal layer.

20. The integrated structure according to claim 15, further comprising a shallow trench isolation disposed in the substrate in the resistor region.
